(19) United States
(12) Patent Application Publication
(10) Pub. No.: US 2026/0064931 A1
(43) Pub. Date: Mar. 5, 2026

(54) CURVILINEAR OPTIMIZATION OF METAL INTERCONNECTS USING SPLINE CURVES

(71) Applicant: GDM Holding LLC, Mountain View, CA (US)

(72) Inventor: Cyrus Behroozi, Menlo Park, CA (US)

(21) Appl. No.: 18/824,350

(22) Filed: Sep. 4, 2024

(51) Int. Cl. G06F 30/3953; G06F 30/327; G06F 30/3312; G06F 30/337; G06F 30/398

(52) U.S. Cl. CPC G06F 30/3953; G06F 30/327; G06F 30/337; G06F 30/398; G06F 30/3312

(57) ABSTRACT

The technology involves optimization of spline-based routing of interconnects. According to one aspect, a method includes receiving a set of weights associated with constraints of a circuit to be fabricated. A first routing of interconnects of the circuit is determined that includes a spline corresponding to one of the interconnects having a straight-line profile. Parameters of the spline are adjusted, based on the set of weights, to transition the spline from a straight-line profile to a curved profile. Adjusting the parameters yields a second routing of the interconnects. A value of a merit function of the second routing of the interconnects is determined. A circuit layout of the interconnects for the circuit is generated based on the value of the merit function.

### BACKGROUND

Performance of a circuit (such as power requirements and/or consumption, timing, and/or size thereof) may be dependent on characteristics and/or arrangement of interconnects of the semiconductor device. Interconnects of a circuit may include electrically conductive connections (e.g., metal wiring) between components (e.g., transistors) of the circuit. As sizes of and/or spaces between transistors and/or interconnects shrink, the cumulative resistance and/or cumulative capacitance (e.g., self-capacitance) of a circuit may increase, which can adversely impact performance.

### SUMMARY

In some approaches, parasitic effects of interconnects (e.g., resistance and capacitance of interconnects) may be modeled and optimized for grid-based routing of interconnects according to a regular (voxel or pixel) grid or unstructured (mesh) grid by solving electromagnetic equations (e.g., Laplace's equation) based on the grid. However, the complexity of modeling and optimizing resistance and capacitance of interconnects increases with the quantity of voxels or mesh points in the grid. An advantage of such approaches is their generality, as they may be used to compute parasitic values for practical, realistic representations of interconnects as well as impractical representations of interconnects (such as a checkerboard grid with alternating voxels of metal and oxide). However, determining parasitic characteristics of interconnects (e.g., resistance and/or capacitance of interconnects) according to such approaches can require breaking representations of interconnects into (and modeled as) voxels or unstructured meshes of the grid.

Aspects of the technology include optimization of spline-based routing of interconnects. In grid-based (e.g., pixel-based) routing of interconnects, paths of interconnects are constrained to straight-line paths between points (e.g., voxels, pixels) of a grid. Thus, for a grid-based routing of interconnects, optimization or improvement of parasitic effects of the interconnects is constrained by the grid-based paths. However, in spline-based routing of interconnects, paths of interconnects are not constrained to following straight-line paths. Rather, in spline-based routing of interconnects, interconnects can take a curved, even circuitous, path between two points. As described herein, allowing interconnects to take curved, even circuitous, paths can provide benefits that previous routing approaches do not, even if the interconnect is longer and/or covers more area of a circuit than previous routing approaches. Thus, embodiments of the present disclosure enable improvement or optimization of parasitic effects of interconnects by modeling interconnects as curved, mathematical abstractions (e.g., splines). For instance, one or more interconnects, and routing thereof, can be represented as splines (e.g., Bezier curves, B-Splines, NURBS, etc.). Physically, an interconnect may include a wire smoothly curving according to a spline-based routing of that interconnect.

The technical benefits of spline-based routing of interconnects include orders of magnitude fewer parameters than grid-based routing of interconnects according to voxels, for example. For instance, an interconnect can be represented as a spline that is defined by as few as four parameters (e.g., control points). A grid-based representation of interconnects, on the other hand, may be defined by values of thousands, or even millions, of voxels or pixels of a grid. Moreover, parameters of splines representing routing of one or more interconnects can be constrained to provide a minimum separation between interconnects (to reduce coupling capacitance), to facilitate lithography in ways that straight-line paths of interconnects required by grid-based routing of interconnects.

Because a spline-based routing of interconnects can be described by significantly fewer parameters than a grid-based routing of interconnects, for example, embodiments of the present disclosure may enable optimization of parasitic characteristics of the interconnects to be performed much faster than other approaches. Moreover, because a spline-based routing of interconnects can be described by fewer parameters, embodiments of the present disclosure may enable optimization of parasitic characteristics of a larger quantity of interconnects, and therefore, may provide increased scalability relative to other approaches.

According to one aspect of the technology, a method includes receiving, by one or more processors, a set of weights associated with one or more constraints of a circuit to be fabricated; determining, by the one or more processors, a first routing of a plurality of interconnects of the circuit including at least one spline corresponding to at least one of the plurality of interconnects having a straight-line profile; adjusting, by the one or more processors based on the set of weights, one or more parameters of the at least one spline to transition the at least one spline from a straight-line profile to a curved profile, wherein adjusting the one or more parameters yields a second routing of the plurality of interconnects; determining, by the one or more processors, a value of a merit function of the second routing of the plurality of interconnects; and generating, by the one or more processors based on the value of the merit function, a circuit layout of the plurality of interconnects for the circuit.

In an example, adjusting the one or more parameters may include relocating a control point associated with the at least one spline from being coincident with a terminal of the circuit to being offset from the terminal. Here, relocating the control point may correspond to an amount of curvature of the at least one spline in the second routing of the plurality of interconnects. A location of the terminal within the circuit may be predetermined and fixed.

Alternatively or additionally to the above, the method may include: adjusting, by the one or more processors based on the set of weights and the value of the merit function, one or more parameters of at least one spline in the second routing of the plurality of interconnects to yield a third routing of the plurality of interconnects; and determining, by the one or more processors, a value of a merit function of the third routing of the plurality of interconnects. Here, generating the circuit layout may be further based on the value of the merit function of the third routing of the plurality of interconnects.

Alternatively or additionally to the above, the set of weights may be indicative of one or more selected (e.g., critical) interconnects of the plurality of interconnects. Alternatively or additionally to the above, the method may include determining whether the second routing of the plurality of interconnects includes a minimum separation between any two of the plurality of interconnects. Here, generating the circuit layout may be further based on the determining whether the second routing of the plurality of interconnects includes the minimum separation. The method may include responsive to determining that the second routing of the plurality of interconnects includes less than the minimum separation: adjusting, by the one or more processors based on the set of weights, one or more parameters of at least one spline of the second routing of the plurality of interconnects to yield a third routing of the plurality of interconnects. Adjusting the one or more parameters of the at least one spline in the second routing of the plurality of interconnects may include adjusting a taper of an interconnect corresponding to the at least one spline based on determining that the second routing of the plurality of interconnects includes less than the minimum separation.

Alternatively or additionally to the above, the method may include adjusting a taper of an interconnect corresponding to the at least one spline based on the value of the merit function. Alternatively or additionally to the above, the circuit may be implemented on a field-programmable gate array (FPGA) device. Alternatively or additionally to the above, the circuit may be an application-specific integrated circuit (ASIC) device or other IC-based device.

According to another aspect of the technology, a system is provided that comprises memory configured to store at least one of a set of weights associated with one or more constraints of a circuit to be fabricated, and one or more processors operatively coupled to the memory. The one or more processors are configured to: determine a first routing of a plurality of interconnects of the circuit including at least one spline corresponding to at least one of the plurality of interconnects having a straight-line profile; adjust, based on the set of weights, one or more parameters of the at least one spline to transition the at least one spline from a straight-line profile to a curved profile, wherein the adjustment of the one or more parameters yields a second routing of the plurality of interconnects; determine a value of a merit function of the second routing of the plurality of interconnects; and generate, based on the value of the merit function, a circuit layout of the plurality of interconnects for the circuit.

In an example, the one or more processors may be further configured to adjust the one or more parameters by being configured to relocate a control point associated with the at least one spline from being coincident with a terminal of the circuit to being offset from the terminal. Here, the relocation of the control point may correspond to an amount of curvature of the at least one spline in the second routing of the plurality of interconnects. A location of the terminal within the circuit may be predetermined and fixed.

Alternatively or additionally to the above, the one or more processors may be further configured to: adjust, based on the set of weights and the value of the merit function, one or more parameters of at least one spline in the second routing of the plurality of interconnects to yield a third routing of the plurality of interconnects; and determine a value of a merit function of the third routing of the plurality of interconnects. Here, the one or more processors may be further configured to generate the circuit layout further based on the value of the merit function of the third routing of the plurality of interconnects.

Alternatively or additionally to the above, the set of weights may be indicative of one or more selected (e.g., critical) interconnects of the plurality of interconnects. Alternatively or additionally to the above, the one or more processors may be further configured to determine whether the second routing of the plurality of interconnects includes a minimum separation between any two of the plurality of interconnects. Here, the one or more processors may be further configured to generate the circuit layout further based on the determining whether the second routing of the plurality of interconnects includes the minimum separation. The one or more processors may be further configured to, responsive to a determination that the second routing of the plurality of interconnects includes less than the minimum separation: adjust, based on the set of weights, one or more parameters of at least one spline of the second routing of the plurality of interconnects to yield a third routing of the plurality of interconnects. The one or more processors may be further configured to adjust the one or more parameters of the at least one spline in the second routing of the plurality of interconnects by being configured to: adjust a taper of an interconnect corresponding to the at least one spline based on determining that the second routing of the plurality of interconnects includes less than the minimum separation.

Alternatively or additionally to the above, tnjuy6he one or more processors may be further configured to adjust a taper of an interconnect corresponding to the at least one spline based on the value of the merit function. Alternatively or additionally to the above, the circuit may be implemented on a field-programmable gate array (FPGA) device. Alternatively or additionally to the above, the circuit may be an application-specific integrated circuit (ASIC) device or other IC-based device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates an integrated circuit design flow in accordance with aspects of the technology.

FIG. 2 illustrates an example system that may be employed with aspects of the technology.

FIGS. 3A-B illustrate an example of an optimization of splines in accordance with aspects of the technology.

FIGS. 4A-B illustrate, in graphical form, an example of an optimization of spline-based routing of interconnects in accordance with aspects of the technology.

FIGS. 5A-B illustrate, in circuit layout form, an example of an optimization of routing of interconnects in accordance with aspects of the technology.

FIG. 6 illustrates an example method in accordance with aspects of the technology.

### DETAILED DESCRIPTION

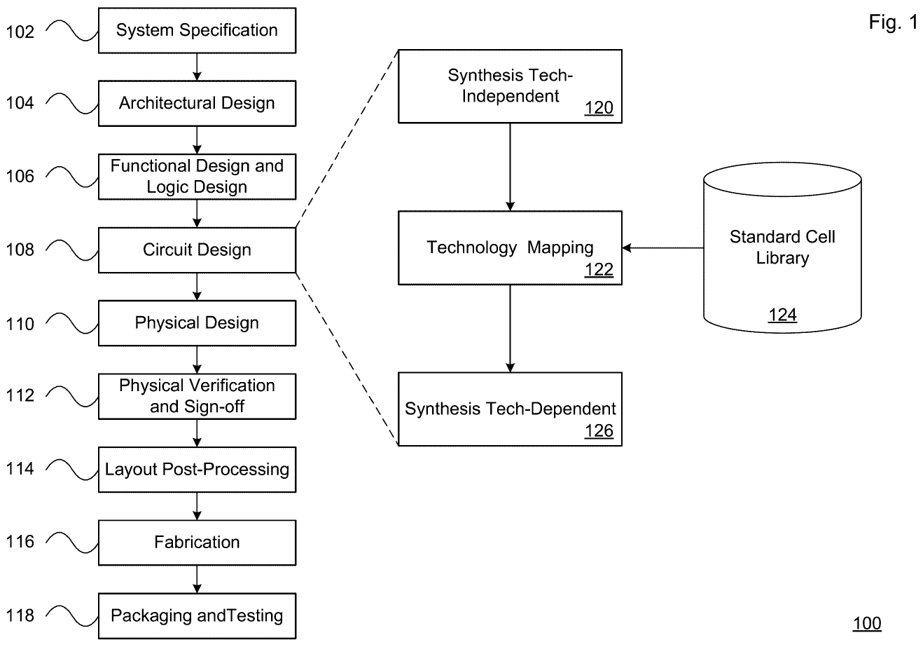

FIG. 1 illustrates an exemplary integrated circuit design flow 100 for use with aspects of the technology, including generating a circuit design and/or fabricating an integrated circuit that incorporates optimization of spline-based representations of interconnects. As shown, the design flow may include preparing a system specification at block 102, such as to identify system-level requirements for the integrated circuit. The system specification is intended to capture the overall goal of the desired integrated circuit. This may include determining the device's cost, performance, general architecture, how off-chip communication will be conducted, etc. The process flow may also include performing architectural design at block 104. At this stage, the design's architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design's specification to achieve the functional behavior of the desired system. Logic design involves adding the design's structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as resistors, capacitors, and/or transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. During this stage, the system may perform optimization of curvilinear interconnects, alternatively or additionally to any other layout operations. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves maps the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

### Example Integrated Circuit Development System

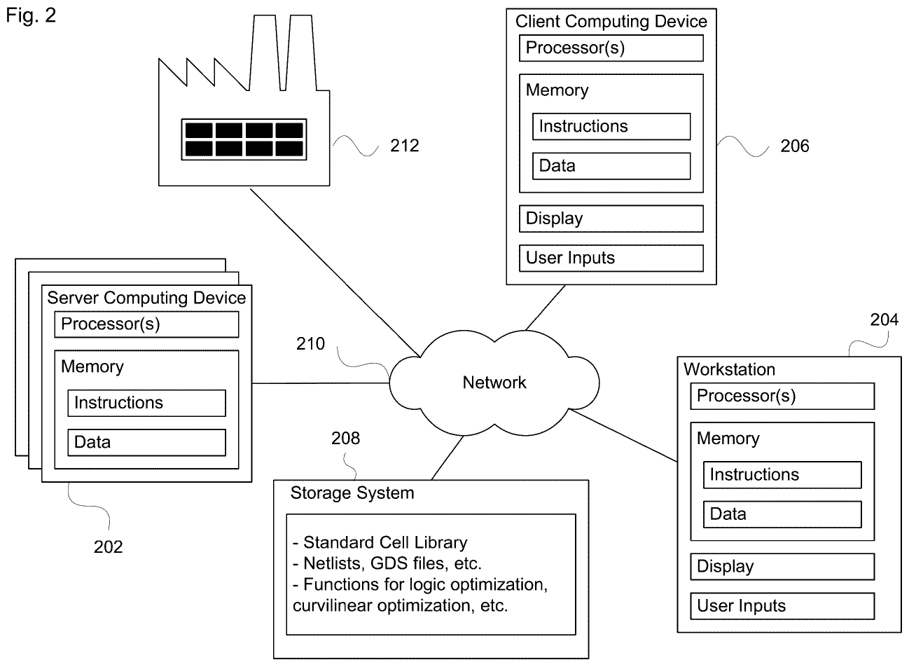

One example of a system for performing circuit design is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing unites (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

Moreover, reference to “one or more processors” herein includes situations where a set of processors may be configured to perform one or more operations. Any combination of such a set of processors may perform individual operations or a group of operations. This may include two or more CPUs, GPUs or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. The instructions may include a method for a optimization of spline-based routing of interconnects as discussed herein.

The data may be retrieved, stored or modified by processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store a set of weights associated with performing optimizations and other processes as well as instructions for performing optimizations and other processes described herein.

### Optimization of Spline-Based Representation of Interconnects

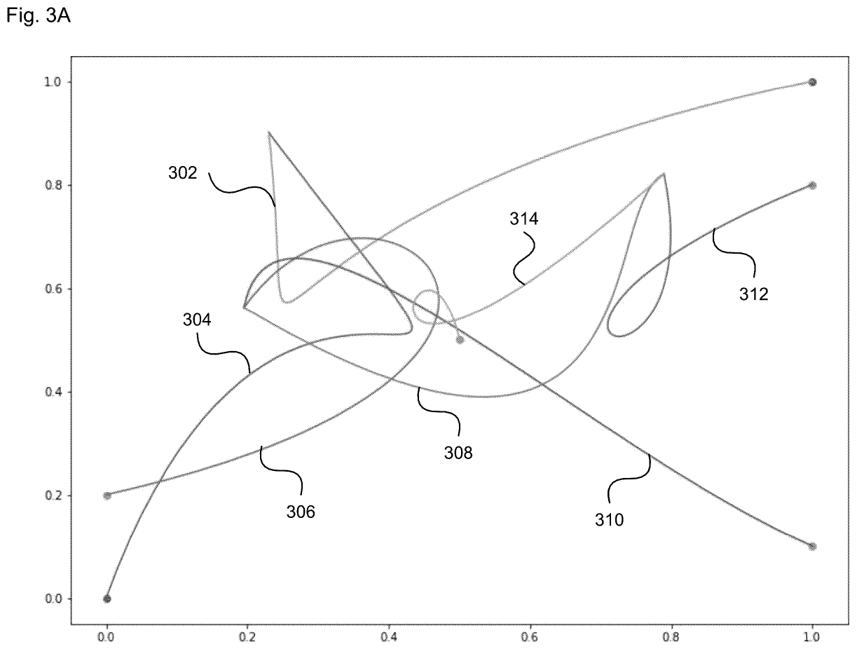

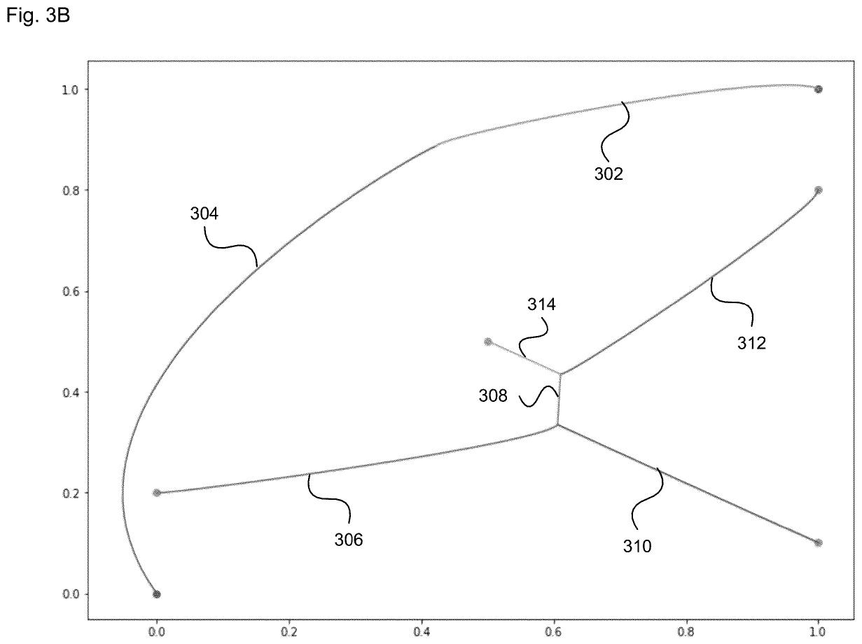

FIGS. 3A-B illustrate an example of an optimization of splines in accordance with aspects of the technology. FIG. 3A illustrates a pre-optimization (initial) state of splines 302, 304, 306, 308, 310, 312 and 314. In FIG. 3A, each of the splines 302, 304, 306, 308, 310, 312 and 314 is a cubic Bezier curve having seventeen parameters of random values. FIG. 3B illustrates an optimized state of the splines 302, 304, 306, 308, 310, 312 and 314. As described herein, the splines 302, 304, 306, 308, 310, 312 and 314 each represent an interconnect, and routing thereof.

As shown in FIG. 3A, the splines 302, 304, 306, 308, 310, 312 and 314 take wandering paths between their respective endpoints, sometimes crossing over other splines (such as the splines 306 and 308) and sometimes crossing over itself as in the spline 312. As shown in FIG. 3B, after one or more iterations of optimization based on one or more parameters (such as self-capacitance and/or coupling-capacitance), the splines 302, 304, 306, 308, 310, 312 and 314 take more direct paths between their respective endpoints without the splines 302, 304, 306, 308, 310, 312 and 314 crossing over another or itself. In this example, the optimization described herein caused each of the splines 302, 304, 306, 308, 310, 312 and 314 to not to cross over other splines or itself to reduce or minimize self-capacitance and/or coupling-capacitance. As described herein, one or more parameters used to optimize the splines 302, 304, 306, 308, 310, 312 and 314 can be constraints on interconnects (such as self-capacitance and/or coupling-capacitance).

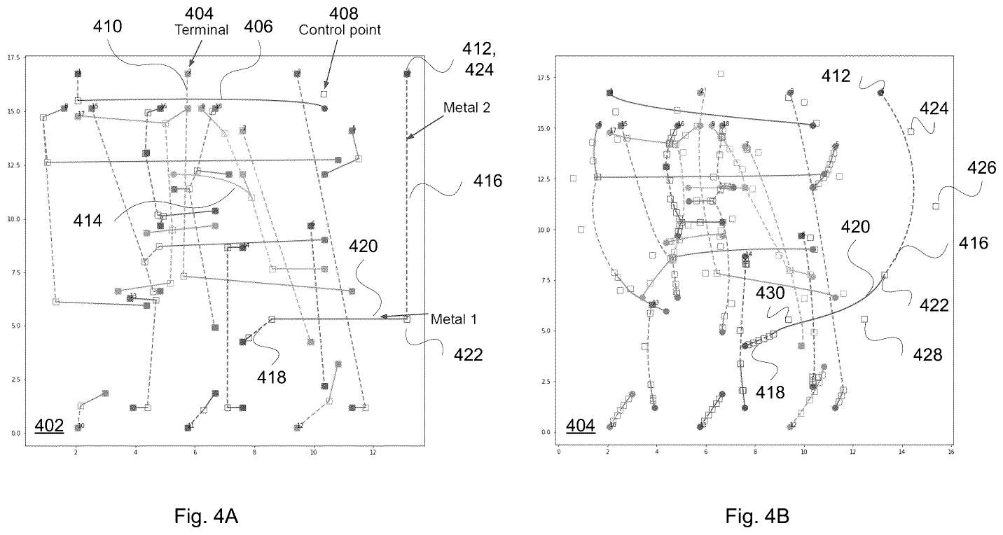

FIGS. 4A-B illustrate an example of an optimization of routing of interconnects in accordance with aspects of the technology. Here, control points are indicated by squares and terminals are indicated by circles. Note that, in some instances, a terminal and a control point are coincident such that some squares appear “filled-in”. However, no difference is implied between a “empty” square and a “filled-in” square.

FIGS. 4A-B illustrate optimization of routing of interconnects of an exemplary two-bit adder. In FIGS. 4A-B, solid lines (e.g., splines 406 and 420) represent interconnects associated with a metal layer (e.g., Metal 1) of the two-bit adder, and dashed lines (e.g., splines 410, 416 and 418) represent interconnects associated a different metal layer (e.g., Metal 2) of the two-bit adder. A solid line may cross a dashed line, and vice versa.

FIG. 4A illustrates a pre-optimization state 402 of routing of interconnects of the two-bit adder. As used herein, “pre-optimization state” may refer to an initial state of a routing problem. Such an initial state can include grid-based routing generated by one or more previous routing approaches. As illustrated in FIG. 4A, in a grid-based routing of interconnects, paths of at least one of the interconnects are constrained to straight-line paths between points of a grid. Terminals of the two-bit adder can be located at points of that grid.

FIG. 4B illustrates an optimized state 404 of routing of the interconnects of the two-bit adder shown in FIG. 4A. The scale of FIG. 4B is smaller than that of FIG. 4A by virtue of a wider range being shown on the axes of FIG. 4B relative to FIG. 4A. This is due to changes in routing of the interconnects to include curved paths shown in FIG. 4B relative to FIG. 4A as a result of the example optimization. A curved path can cover a greater area (e.g., have a larger footprint) than a straight-line path. The routing of the interconnects shown in FIG. 4B has a larger footprint than the routing of the interconnects shown in FIG. 4A, resulting in the wider range being shown on the axes of FIG. 4B. Even though the optimized state 404 has a larger footprint, the curved paths of the routing of the interconnects provide benefits (e.g., reduced parasitic characteristics) over the pre-optimization state 402.

As a result of one or more iterations of optimization, one or more of the interconnects transition from a straight-line path in the pre-optimization state 402 shown in FIG. 4A to curved paths in the optimized state 404 shown in FIG. 4B. For example, compare the interconnect represented by the splines 416, 420 and 418 in the pre-optimization state 402 to the splines 416, 420 and 418 in the optimized state 404. Splines that have a straight-line profile (e.g., in the pre-optimization state 402) have a control point that is coincident with a terminal. In contrast, splines that have a curved profile (e.g., in the optimized state 404) have a control point that is not coincident with (offset from) a terminal.

As a result of one or more iterations of optimization, in the optimized state 404, one or more control points associated with one or more splines having a straight-line profile are relocated such that those control points are no longer coincident with (offset from) one or more terminals of the two-bit adder. For example, in the optimized state 404, at least the splines 416 and 420 transition from a straight-line profile to a curved profile. As shown in FIG. 4A, in the pre-optimization state 402, the control point 424 associated with the spline 416, for example, is coincident with the terminal 412. In contrast, as shown in FIG. 4B, in the optimized state 404, the control point 424 is no longer coincident with the terminal 412 (is offset from the terminal 412) and is located below and to the right of the terminal 412. As a result of the relocation of the control point 424, the spline 416 curves to the right.

Although not illustrated in the example described in association with FIGS. 4A-B, optimization of representations of interconnects described herein can include introducing one or more additional control points associated with one or more splines representing one or more interconnects in a pre-optimization state.

Although representing interconnects using curved splines may seem inefficient relative to representing interconnects using straight splines (e.g., curved splines have more control points in different locations), spline-based routing of interconnects using curved paths can provide improved (e.g., reduced) parasitic characteristics relative to grid-based routing of interconnects using straight-line paths. Thus, embodiments of the present disclosure are beneficial in that parasitic characteristics are optimized for spline-based routing of interconnects using curved paths.

Optimization of parasitic characteristics for spline-based routing of interconnects using curved paths may avoid poor-performing regions of a semiconductor device that other approaches (e.g., optimization of parasitic characteristics for gridded representations of interconnects) do not. For instance, in situations where terminal locations are in congested regions (e.g., large quantities of terminals in an area (terminals per area), short distances separating terminals), grid-based routing of interconnects coupled to these terminals can be difficult, if not impossible. However, spline-based routing of interconnects (e.g., with curved splines) can be achieved for terminal locations that are in congested regions.

A grid-based routing of interconnects, such as that shown in FIG. 4A, may be optimized, as shown in FIG. 4B, to reduce, or minimize, certain constraints (e.g., parasitic characteristics including, but not limited to, a cumulative resistance, self-capacitance and/or coupling capacitance) of the interconnects. Respective resistance, self-capacitance and/or coupling capacitance of each individual interconnect may be summed in a merit function to provide a cumulative merit value or loss. Optimization of a routing of interconnects can include increasing or maximizing a merit value and/or decreasing or minimizing a merit loss.

Optimization of routing of one or more critical interconnects (e.g., associated with critical paths) can be prioritized over optimization of routing of other interconnects. As used herein, “critical path” can refer to the slowest group of transistors and its associated interconnects in a circuit. Often, certain input-to-output paths of a circuit may propagate faster than other input-to-output paths of that circuit. One of those input-to-output paths can limit the overall performance (e.g., speed, timing) of the circuit. A critical path may include a sequence of particular transistors and interconnects. Interconnects of a critical path can be prioritized at the expense of non-critical paths of the circuit (e.g., input-to-output paths that do not limit the overall performance of the circuit). For instance, one or more non-critical paths may be detoured and/or incur an increase in parasitic characteristics so that one or more critical paths can take a more direct path, which can improve the overall performance of the circuit.

For example, by applying weights to respective contributions of the critical interconnects to a merit function, optimization of parasitic characteristics of critical interconnects can be prioritized over optimization of parasitic characteristics of other, non-critical interconnects. For instance, parasitic characteristics of critical interconnects may be reduced, as a result of optimization, at the cost of lesser or no reduction of parasitic characteristics of non-critical interconnects as a result of optimization.

As discussed above, optimization of a routing of interconnects may relocate control points as the splines representing interconnects are adjusted (e.g., curved) to satisfy goals and/or constraints of the optimization. For instance, as shown in FIG. 4A, the interconnect represented by the splines 416, 420 and 418 in the pre-optimized state 402 includes mostly straight portions and a nearly right angle relationship between the portion in the Metal 1 layer represented by the spline 420 and the portion in the Metal 2 layer represented by the spline 416. However, after optimization as shown in FIG. 4B, the transitions from the portion of that interconnect in the Metal 2 layer represented by the spline 418 to the portion in the Metal 1 layer represented by the spline 420 to the portion in the Metal 2 layer represented by the spline 416 are much smoother. The optimization has relocated control points, the control points 424, 426, 428 and 430 for the splines 416 and 420, for example, transitioning the splines 416 and 420 from having mostly straight-line profiles to having curved profiles.

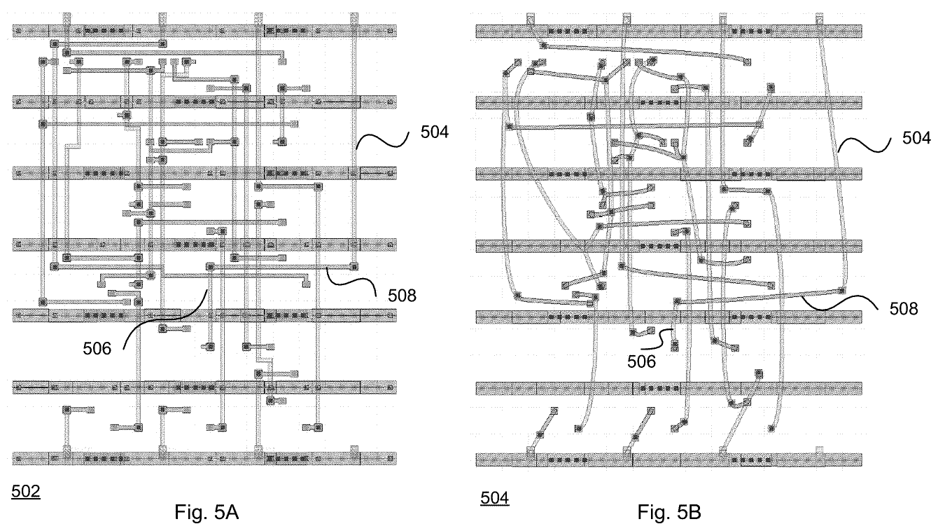

The optimization shown in FIG. 4B results in the splines 420 and 416 extending and curving further right than shown in FIG. 4A. In FIGS. 4A-B, the pre-optimized state 402 and the optimized state 404 of the routing of interconnects are described in a mathematical sense. However, in FIGS. 5A-B, the pre-optimized state 502 and the optimized state 504 of the routing of interconnects of the two-bit adder are described in a physical circuitry sense. Because there are physical constraints associated with circuitry, parameters of one or more of the interconnects in the optimized state 404 may not be possible or permissible when implemented with circuitry in the optimized state 504. When values of parameters of interconnects, or routing thereof, are not possible or permissible to be implemented with circuitry, parameters from a prior iteration of an optimization of the routing of interconnects may be used to implement the optimized routing of interconnects in circuitry (e.g., via lithography).

FIGS. 5A-B illustrate, in circuit layout form, an example of an optimization of routing of interconnects in accordance with aspects of the technology. FIG. 5A illustrates a pre-optimization state 502 of routing of interconnects and corresponds to the pre-optimization state 402 of the routing of interconnects shown in FIG. 4A. FIG. 5B illustrates an optimized state 504 of routing of interconnects shown in FIG. 5A and corresponds to the optimized state 404 of the routing of interconnects shown in FIG. 4B.

In FIGS. 5A-B, the shading of the interconnects corresponds to the metal layer in which the interconnect is to be formed. For example, the interconnect 508 shown in FIGS. 5A-B, which corresponds to the spline 420 shown in FIGS. 4A-B, corresponds to the Metal 1 layer. The interconnect 504 shown in FIGS. 5A-B, which corresponds to the spline 416 shown in FIGS. 4A-B, and the interconnect 506 shown in FIGS. 5A-B, which corresponds to the spline 418 shown in FIGS. 4A-B, correspond to the Metal 2 layer.

As a result of one or more iterations of optimization, one or more interconnects in the pre-optimization state 502 shown in FIG. 5A transition from a grid-based routing using straight-line paths to a spline-based routing using curved paths in the optimized state 504 shown in FIG. 5B. For example, compare the routing of the interconnects 504, 508 and 506 in the pre-optimization state 502 shown in FIG. 5A to the routing of the interconnects 504, 508 and 506 in the optimized state 504 shown in FIG. 5B.

As discussed in association with FIGS. 4A-B, the optimized state 404 includes the splines 420 and 416 extending further right than shown in FIG. 4A. However, because FIGS. 5A-B are illustrated in circuit form, physical constraints on the interconnects, such as size constraints of the semiconductor device, may be taken into account that were not in the example optimization illustrated by FIGS. 4A-B. As described above, the optimized state 404 shown in FIG. 4B includes the splines 416 and 420 has a larger footprint than the pre-optimization state 402 shown in FIG. 4A. However, the optimized state 504 of the routing of the interconnects shown in FIG. 5B must be within the same boundaries (e.g., within a same footprint) as the pre-optimization state 502 of the routing of the interconnects shown in FIG. 5A. But that is not to say that the optimized 504 of the routing of the interconnects must have the same boundaries or footprint as the 504 of the routing of the interconnects in the pre-optimization state 502 of the routing of the interconnects. Thus, by way of example, the routing of the interconnects 504 and 508 in the optimized state 504 shown in FIG. 5B do not completely match the paths of the splines 416 and 420 in the optimized state 404 shown in FIG. 4B.

In some embodiments, the optimization can include introducing or adjusting a taper (e.g., a thickness or diameter) of one or more interconnects to further reduce parasitic characteristic of the interconnects. For instance, optimum wire geometry of an interconnect may include a shallow taper (e.g., a thinning).

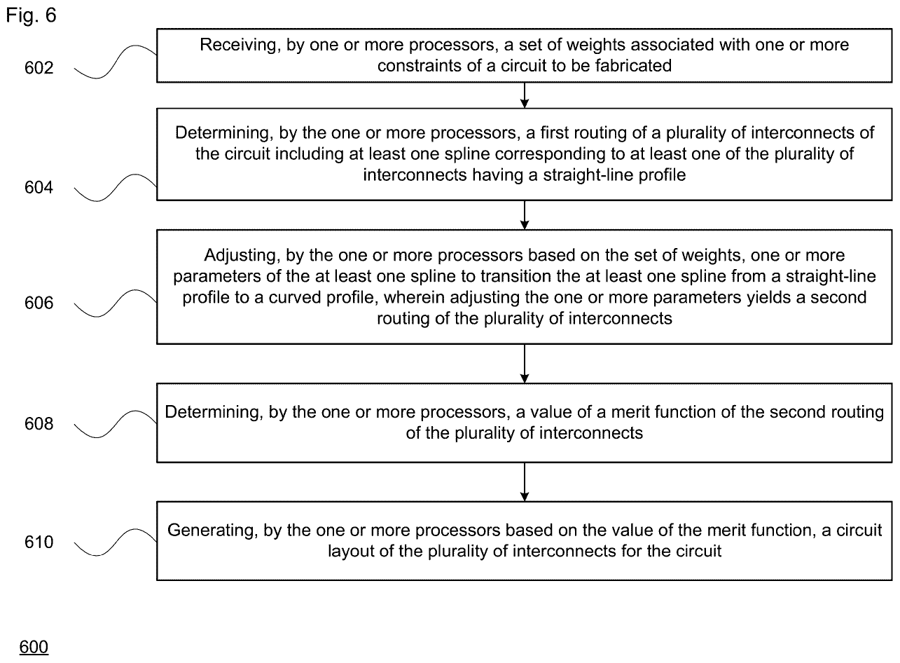

FIG. 6 illustrates an example method 600 in accordance with the above discussion. The method 600 includes, at block 602, receiving, by one or more processors, a set of weights associated with one or more constraints of a circuit to be fabricated. At block 604, the method 600 includes determining, by the one or more processors, a first routing of a plurality of interconnects of the circuit including at least one spline corresponding to at least one of the plurality of interconnects having a straight-line profile. At block 606, the method 600 includes adjusting, by the one or more processors based on the set of weights, one or more parameters of the at least one spline to transition the at least one spline from a straight-line profile to a curved profile. Adjusting the one or more parameters yields a second routing of the plurality of interconnects. At block 608, the method 600 includes determining, by the one or more processors, a value of a merit function of the second routing of the plurality of interconnects. And, at block 610, the method 600 includes generating, by the one or more processors based on the value of the merit function, a circuit layout of the plurality of interconnects for the circuit.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A method, comprising:
receiving, by one or more processors, a set of weights associated with one or more constraints of a circuit to be fabricated;
determining, by the one or more processors, a first routing of a plurality of interconnects of the circuit including at least one spline corresponding to at least one of the plurality of interconnects having a straight-line profile;
adjusting, by the one or more processors based on the set of weights, one or more parameters of the at least one spline to transition the at least one spline from a straight-line profile to a curved profile, wherein adjusting the one or more parameters yields a second routing of the plurality of interconnects;
determining, by the one or more processors, a value of a merit function of the second routing of the plurality of interconnects; and
generating, by the one or more processors based on the value of the merit function, a circuit layout of the plurality of interconnects for the circuit.

2. The method of claim 1, wherein adjusting the one or more parameters includes relocating a control point associated with the at least one spline from being coincident with a terminal of the circuit to being offset from the terminal.

3. The method of claim 2, wherein relocating the control point corresponds to an amount of curvature of the at least one spline in the second routing of the plurality of interconnects.

4. The method of claim 2, wherein a location of the terminal within the circuit is predetermined and fixed.

5. The method of claim 1, further comprising:
adjusting, by the one or more processors based on the set of weights and the value of the merit function, one or more parameters of at least one spline in the second routing of the plurality of interconnects to yield a third routing of the plurality of interconnects; and
determining, by the one or more processors, a value of a merit function of the third routing of the plurality of interconnects.

6. The method of claim 5, wherein generating the circuit layout is further based on the value of the merit function of the third routing of the plurality of interconnects.

7. The method of claim 1, wherein the set of weights is indicative of one or more selected interconnects of the plurality of interconnects.

8. The method of claim 1, further comprising determining whether the second routing of the plurality of interconnects includes a minimum separation between any two of the plurality of interconnects.

9. The method of claim 8, wherein generating the circuit layout is further based on the determining whether the second routing of the plurality of interconnects includes the minimum separation.

10. The method of claim 9, further comprising, responsive to determining that the second routing of the plurality of interconnects includes less than the minimum separation:
adjusting, by the one or more processors based on the set of weights, one or more parameters of at least one spline of the second routing of the plurality of interconnects to yield a third routing of the plurality of interconnects.

11. The method of claim 10, wherein adjusting the one or more parameters of the at least one spline in the second routing of the plurality of interconnects includes adjusting a taper of an interconnect corresponding to the at least one spline based on determining that the second routing of the plurality of interconnects includes less than the minimum separation.

12. The method of claim 1, further comprising adjusting a taper of an interconnect corresponding to the at least one spline based on the value of the merit function.

13. The method of claim 1, wherein the circuit is implemented on a field-programmable gate array (FPGA) device or an application-specific integrated circuit (ASIC) device.

14. A system, comprising:
memory configured to store at least one of a set of weights associated with one or more constraints of a circuit to be fabricated; and
one or more processors operatively coupled to the memory, the one or more processors being configured to:
determine a first routing of a plurality of interconnects of the circuit including at least one spline corresponding to at least one of the plurality of interconnects having a straight-line profile;
adjust, based on the set of weights, one or more parameters of the at least one spline to transition the at least one spline from a straight-line profile to a curved profile, wherein the adjustment of the one or more parameters yields a second routing of the plurality of interconnects;
determine a value of a merit function of the second routing of the plurality of interconnects; and
generate, based on the value of the merit function, a circuit layout of the plurality of interconnects for the circuit.

15. The system of claim 14, wherein the one or more processors are further configured to adjust the one or more parameters by being configured to relocate a control point associated with the at least one spline from being coincident with a terminal of the circuit to being offset from the terminal.

16. The system of claim 15, wherein the relocation of the control point corresponds to an amount of curvature of the at least one spline in the second routing of the plurality of interconnects.

17. The system of claim 14, wherein the one or more processors are further configured to:
adjust, based on the set of weights and the value of the merit function, one or more parameters of at least one spline in the second routing of the plurality of interconnects to yield a third routing of the plurality of interconnects; and
determine a value of a merit function of the third routing of the plurality of interconnects.

18. The system of claim 17, wherein the one or more processors are further configured to generate the circuit layout further based on the value of the merit function of the third routing of the plurality of interconnects.

19. The system of claim 14, wherein the set of weights is indicative of one or more selected interconnects of the plurality of interconnects.

20. The system of claim 14, wherein the one or more processors are further configured to determine whether the second routing of the plurality of interconnects includes a minimum separation between any two of the plurality of interconnects.

21. The system of claim 20, wherein the one or more processors are further configured to generate the circuit layout further based on the determining whether the second routing of the plurality of interconnects includes the minimum separation.

22. The system of claim 21, wherein the one or more processors are further configured to, responsive to a determination that the second routing of the plurality of interconnects includes less than the minimum separation:
adjust, based on the set of weights, one or more parameters of at least one spline of the second routing of the plurality of interconnects to yield a third routing of the plurality of interconnects.

23. The system of claim 22, wherein the one or more processors are further configured to adjust the one or more parameters of the at least one spline in the second routing of the plurality of interconnects by being configured to:
adjust a taper of an interconnect corresponding to the at least one spline based on determining that the second routing of the plurality of interconnects includes less than the minimum separation.

24. The system of claim 14, wherein the one or more processors are further configured to adjust a taper of an interconnect corresponding to the at least one spline based on the value of the merit function.
